(19) United States
(12) Patent Application Publication
(10) Pub. No.: US 2025/0038857 A1
(43) Pub. Date: Jan. 30, 2025

(54) Optical Circuit

(71) Applicant: Nippon Telegraph and Telephone Corporation, Tokyo (JP)

(72) Inventors: Shigeru Kanazawa, Musashino-shi, Tokyo (JP); Takahiko Shindo, Musashino-shi, Tokyo (JP); Meishin Chin, Musashino-shi, Tokyo (JP); Shohei Kosuga, Musashino-shi, Tokyo (JP)

(21) Appl. No.: 18/716,396

(22) PCT Filed: Dec. 7, 2021
(86) PCT No.: PCT/JP2021/044968

§ 371 Date: Jun. 4, 2024

(51) Int. Cl. H04B 10/50; G02F 1/21; G02F 1/225; H01S 5/00

(52) U.S. Cl. CPC H04B 10/505; G02F 1/212; G02F 1/2257; H01S 5/0085

(57) ABSTRACT

A novel mounting form of a capacitor for blocking a bias voltage in an optical circuit including an optical chip including an optical modulator, a wiring board that supplies a high-frequency electrical signal, and a connection substrate that connects the optical chip and the wiring board is disclosed. A wiring board and a light-modulating light source chip are mounted on a subcarrier. The wiring board and the light-modulating light source chip are connected by a connection substrate, and a high-frequency electrical signal is input to a modulation input electrode from the outside of the optical circuit. The connection substrate includes a termination resistor on a first surface connected to two substrates by gold bumps. One electrode of the termination resistor is connected to an end of a transmission line on the modulation input electrode side. The other electrode of the termination resistor is connected to a high impedance line.

### TECHNICAL FIELD

The present invention relates to a device used in a network. Specifically, the present invention relates to an optical circuit that can be used for high-speed Ethernet or the like.

### BACKGROUND ART

In order to respond to the strong demand for bandwidth accompanying the recent spread of mobile and cloud services, studies on high-speed and large-capacity networks are active. With the advent of the 5G era of wireless communication, a transmission speed of widely used Ethernet of 400 Gbps has already been put into practical use, and Beyond 400G Ethernet has also been studied. In an optical circuit such as an optical transmission/reception module for optical fiber transmission, improvement in performance, miniaturization, and cost reduction are required.

In the Ethernet standards, a miniaturized transceiver (optical transceiver) is standardized, and an optical circuit including an optical modulator is an important device. In order to adapt an optical transmitter to high-speed transmission, flip-chip mounting including an optical chip and a high-frequency signal substrate has been proposed as a mounting structure suitable for high-speed operation.

### CITATION LIST

### Non Patent Literature

Non Patent Literature 1: S. kanazawa et. al., “Flip-Chip Interconnection Lumped-Electrode EADFB Laser for 100-Gb/s/A Transmitter,” IEEE Photon. Technol. Lett., vol. 27, no. 16, pp. 1699-1701, 2015

### SUMMARY OF INVENTION

### Technical Problem

In an optical circuit including an optical modulator using flip-chip mounting of the related art, mounting of a capacitor necessary for applying a bias voltage has been a problem in terms of miniaturization and reliability of the optical circuit.

### Solution to Problem

One aspect of the present invention is an optical circuit including: a wiring board that receives a high-frequency electrical signal from the outside; a light source chip including an optical modulator; a subcarrier on which the wiring board and the light source chip are mounted; a connection substrate having, on a first surface, a transmission line connecting between a signal line of the wiring board and a modulation input terminal of the light source chip, and having a termination resistor at one end of the transmission line on a modulation input side; and a capacitor connected to the ground in series with the termination resistor on the connection substrate.

### Advantageous Effects of Invention

Provided is an optical circuit that is suitable for high-speed operation and includes a miniaturized and highly reliable optical modulator.

### BRIEF DESCRIPTION OF DRAWINGS

FIG. 1 is a diagram illustrating a configuration of a subassembly of the related art including a light-modulating light source chip.

FIG. 2 is a diagram illustrating a configuration of an optical circuit of Example 1 including a light-modulating light source chip.

FIG. 3 is a diagram for describing a configuration of a connection substrate in an optical circuit of the present disclosure in more detail.

FIG. 4 is a diagram illustrating comparison of modulation frequency characteristics between optical circuits of Example 1 and the related art.

FIG. 5 is a diagram illustrating modulation frequency characteristics of an optical circuit having connection substrates with different substrate thicknesses.

FIG. 6 is a diagram illustrating an optical circuit of Example 2 including an optical modulator chip and another connection substrate.

FIG. 7 is a diagram illustrating comparison of modulation frequency characteristics between an optical circuit of Example 2 and an optical circuit of the related art.

### DESCRIPTION OF EMBODIMENTS

An optical circuit of the present disclosure provides a novel mounting form of a capacitor for blocking a bias voltage in an optical circuit including an optical chip including an optical modulator, a wiring board that supplies a high-frequency electrical signal, and a connection substrate that connects between the optical chip and the wiring board. In the following description, first, a problem in mounting a capacitor in an optical circuit according to a structure of flip-chip mounting of the related art will be described. Next, a novel configuration for mounting a capacitor in an optical circuit including the optical modulator of the present disclosure will be described.

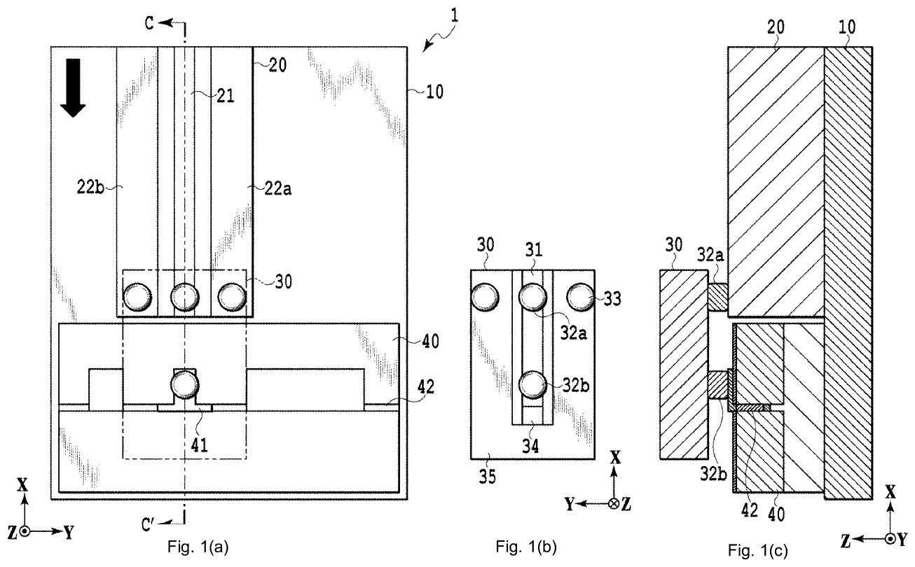

FIG. 1 is a diagram illustrating a configuration of an optical circuit of the related art including a light-modulating light source chip. An optical circuit 1 of FIG. 1 is a component in a module form that can be mounted on a transceiver standardized in the Ethernet, and includes a light-modulating light source chip 40 that is an electro-absorption modulator integrated with DFB laser (EML). A wiring board 20 and the light-modulating light source chip 40 are mounted on a subcarrier 10, and the wiring board 20 and the light-modulating light source chip 40 are connected by a connection substrate 30.

In FIG. 1, (a) illustrates a top view (x-y plane) of the entire optical circuit 1, (c) illustrates a cross-sectional view (x-z plane) of the optical circuit 1 taken along line C-C′, and (b) illustrates a back surface (x-y plane) of the connection substrate 30 mounted on the optical circuit 1. (a) of FIG. 1 illustrates only the four gold bumps between the connection substrate 30 and the light-modulating light source chip 40 and the outline of the connection substrate 30 (double-dot dashed lines) in order to illustrate a connection form with the light-modulating light source chip 40. It should be noted that in the actual optical circuit 1, only the substrate surface or the ground surface of the connection substrate 30 in the top view of (a) of FIG. 1 is visible depending on the type of transmission line.

The light-modulating light source chip 40 includes a laser section using an optical waveguide structure 42 configured as an optical semiconductor and an electro-absorption modulator section. A high-frequency electrical signal as a modulation signal is supplied to a modulation input electrode 41 of the light-modulating light source chip 40 via the wiring board 20 and the connection substrate 30. The wiring board 20 includes a signal line 21 formed on a substrate and ground surfaces 22a and 22b on both sides of the signal line, and constitutes a transmission line. The wiring board 20 functions as a high-frequency wiring board that receives a high-frequency electrical signal from the outside and transmits the high-frequency electrical signal without loss.

Referring to (b) of FIG. 1, the connection substrate 30 includes a ground surface 35 surrounding a transmission line 31 and the vicinity thereof on a surface (connection surface) on a side connected by gold bumps. When a coplanar line is used as the transmission line, the substrate material appears as it is on the opposite side of the connection surface, that is, the upper surface in (a) of FIG. 1. When a grounded coplanar line is used as the transmission line, the opposite side of the connection surface is a ground surface.

One end of the transmission line 31 is connected to the signal line 21 of the wiring board 20 via a gold bump 32a. The other end of the transmission line 31 is connected to the modulation input electrode 41 of the light-modulating light source chip 40 via a gold bump 32b. A modulation signal that is a high-frequency electrical signal is input from the outside of the optical circuit 1 in the upper part of (a) of FIG. 1 to the modulation input electrode 41 in the direction of an arrow via the signal line 21 of the wiring board 20 and the transmission line 31 of the connection substrate 30. Also, the ground surfaces of the wiring board 20 and the connection substrate 30 are also electrically and mechanically connected by two gold bumps on both sides of the gold bump 32a. Such a mounting form of electrically and structurally connecting two different substrates 20 and 40 by means of the facing connection substrate 30 and bumps is known as flip-chip mounting. The structure of flip-chip mounting using the connection substrate 30 does not require a wire for connection between the wiring board 20 and the light-modulating light source chip 40, and thus, is useful for broadening the bandwidth of the light modulation characteristics.

However, in the optical circuit of the related art including the light-modulating light source chip 40 of FIG. 1, a capacitor for blocking a bias voltage which is originally necessary for an efficient operation is not provided, resulting in a simplified circuit configuration. Referring again to (b) of FIG. 1, a termination resistor 34 is mounted between the end of the transmission line 31 of the connection substrate 30 on the side of the modulation input electrode 41 and the ground surface 35 to form a parallel circuit with respect to the modulation input terminal. Usually, it is necessary to apply a bias voltage to the modulation input terminal 41 of the light-modulating light source chip 40. When the bias voltage is applied to the light-modulating light source chip 40, the bias voltage is also applied to the termination resistor 34 at the same time, and thus the power consumption of the optical circuit steadily increases by the amount of the DC current flowing through the termination resistor 34.

Normally, in order to suppress the DC power consumption due to the bias voltage in the electric circuit, the bias path needs to be blocked in a DC manner by a DC blocking capacitor. Specifically, a capacitor is mounted on the subcarrier 10, the termination resistor 34 and the capacitor are electrically connected by wire bonding or the like, and thereby a current flowing through the termination resistor 34 can be blocked. However, in an optical circuit including a light-modulating light source chip, miniaturization has already progressed, and an empty space on the subcarrier 10 is already limited. If a place for mounting the capacitor is secured on the subcarrier, the size of the optical circuit as the subassembly increases, which goes against the demand for miniaturization of the optical circuit. In addition, in the process of directly performing wire bonding on the connection substrate 30 for connection with the capacitor, there arises a problem that the connection between the connection substrate 30 and the gold bumps 32a and 32b breaks due to a physical impact by the bonding tool.

An optical circuit of the present disclosure described below provides a novel capacitor mounting structure that suppresses DC power consumption in the above-described optical modulation circuit and simultaneously satisfies requirements for miniaturization and reliability. In the optical circuit of the present disclosure, a DC blocking capacitor is mounted on a connection substrate. With this configuration, it is not necessary to connect between the capacitor and the termination resistor by wire bonding or the like, and breakage of the electrical connection via the gold bump does not occur.

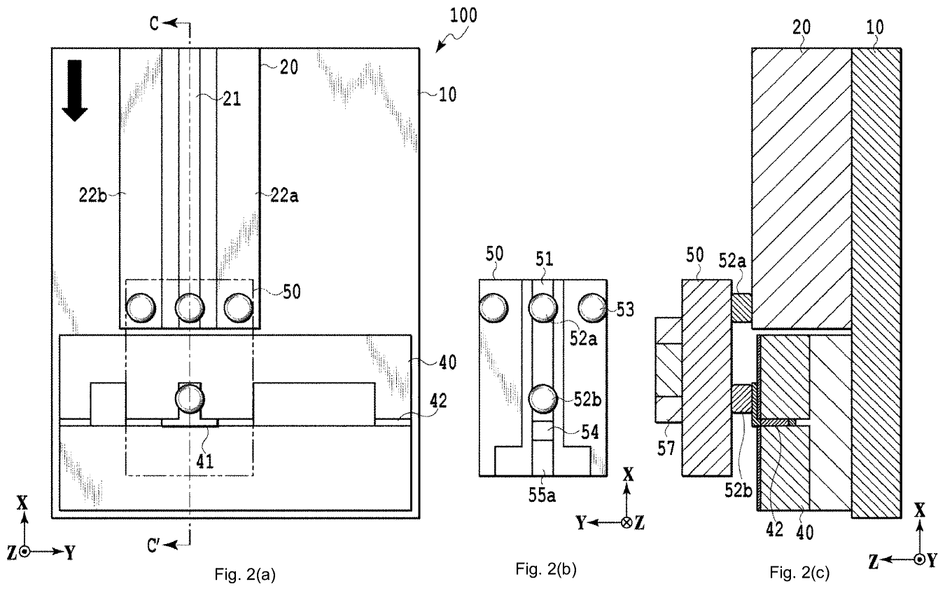

FIG. 2 is a diagram illustrating a configuration of an optical circuit of the present disclosure including a light-modulating light source chip. An optical circuit 100 of FIG. 2 has a form of a subassembly that can be mounted, for example, on a substrate such as an Ethernet transceiver or an optical transmission device. In FIG. 2, (a) illustrates a top view (x-y plane) of the entire optical circuit 100, (c) illustrates a cross-sectional view (x-z plane) of the optical circuit 100 taken along line C-C′, and (b) illustrates a back surface (x-y plane) of a connection substrate 50 mounted on the optical circuit. In the optical circuit 100, similarly to the optical circuit 1 of the related art illustrated in FIG. 1, a wiring board 20 and a light-modulating light source chip 40 are mounted on a subcarrier 10. Similarly to the optical circuit 1, the wiring board 20 and the light-modulating light source chip 40 are connected by the connection substrate 50, and a high-frequency electrical signal is input to a modulation input electrode 41 from the outside of the optical circuit 100. In addition, a transmission line (signal line) leading to the light source chip 40 via the wiring board 20 and the connection substrate 50, and a connection form on the ground are also the same as those in FIG. 1.

A difference from the optical circuit 1 having the structure of the related art illustrated in FIG. 1 lies in the configuration of the connection substrate 50 illustrated in (b) and (c) of FIG. 2. The connection substrate 50 includes a termination resistor 54 on a first surface connected to the two substrates 20 and 40 by gold bumps 52a, 52b, and 53. One electrode of the termination resistor 54 is connected to an end of a transmission line 51 on the modulation input electrode 41 side. The other electrode of the termination resistor 54 is connected to a high impedance line 55a. The high impedance line 55a is continuously formed on a second surface, which is the back surface of the first surface, through the side surface of the connection substrate 50, and is connected to a capacitor 57.

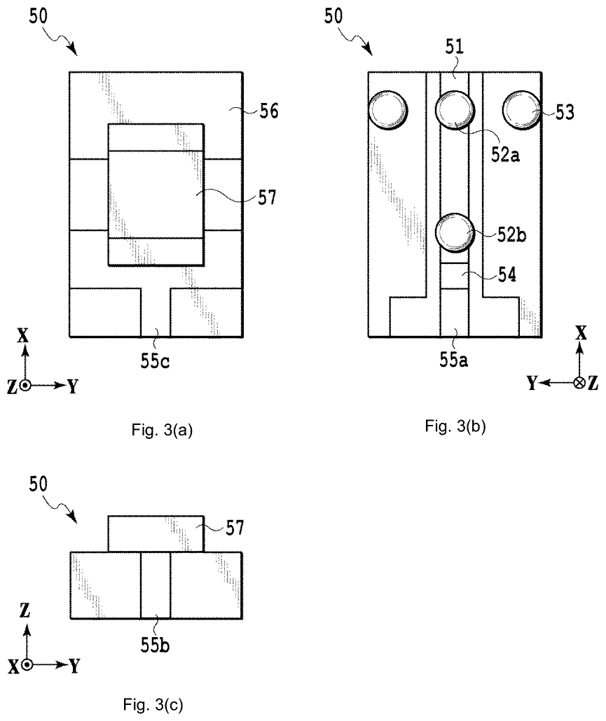

FIG. 3 is a diagram for describing a configuration of the connection substrate in the optical circuit of the present disclosure in more detail. In FIG. 3, (a) illustrates a top view (x-y plane) of the second surface of the connection substrate 50, (b) illustrates a first surface (connection surface) (x-y plane) of the connection substrate 50, and (c) illustrates a side surface (y-z plane) of a short side of the connection substrate. Referring to FIG. 3 (b), one electrode of the termination resistor 54 is connected to the end of the transmission line 51 on the modulation input electrode 41 side. The other electrode of the termination resistor 54 is connected to the high impedance line 55a having a larger distance to the ground surfaces on both sides than the transmission line 51. The high impedance line 55a extends to a high impedance line 55b on the side surface illustrated in (c) and further to a high impedance line 55c on the second surface illustrated in (a), and is connected to the electrode pad of the capacitor. The capacitor 57 is mounted on the second surface of the connection substrate 50, and one electrode pad is connected to the ground.

In the connection substrate 50 described above, the termination resistor 54, the high impedance lines 55a to 55c, and the capacitor 57 are connected in series, and as an electric circuit, this series circuit is inserted between the modulation input terminal and the ground. With this configuration, when a bias voltage is applied to the light-modulating light source chip 40, the current can be blocked by the capacitor 57 in series with the termination resistor 54. It is possible to suppress DC power consumption due to a bias current flowing through the termination resistor. In addition, since the capacitor 57 is mounted on the connection substrate 50, it is not necessary to connect the capacitor 57 and the termination resistor 54 by wire bonding or the like. There is also no breakage of the electrical connection portions formed via the gold bumps due to an impact by the bonding tool.

A further feature of the above-described configuration of the connection substrate is that the high impedance lines 55a to 55c are arranged between the termination resistor 54 and the capacitor 57. The high impedance lines 55a to 55c have a large distance from the ground surface, and have an impedance higher than the characteristic impedance of the transmission line 51 and the optical circuit 100. Therefore, series resonance occurs between the inductive line and the capacitor 57, whereby desired peaking can be generated in the modulation frequency response characteristics. The capacitor 57 and the high impedance lines 55a to 55c can be three-dimensionally arranged on the connection substrate 50, and can also contribute to miniaturization of the optical circuit.

Therefore, the optical circuit of the present disclosure can be implemented on the assumption that the optical circuit includes a wiring board that receives a high-frequency electrical signal from the outside a light source chip including an optical modulator, a subcarrier on which the wiring board and the light source chip are mounted, a connection substrate having, on a first surface, a transmission line connecting between a signal line of the wiring board and a modulation input terminal of the light source chip, and having a termination resistor at one end of the transmission line on a modulation input side, and a capacitor connected to the ground in series with the termination resistor on the connection substrate.

As the connection substrate 50, aluminum nitride having the same value as the thermal expansion coefficient of the InP substrate generally used in the light-modulating light source chip 40 is used. For this reason, a structure in which stress generated by environmental temperature fluctuation is not applied to the connection portion of the chip is employed. Hereinafter, a specific configuration example will be described as Example 1 of the optical circuit of the present disclosure.

### Example 1

An optical circuit of Example 1 including a light-modulating light source chip (light source chip) was produced according to the structure of the connection substrate illustrated in FIGS. 2 and 3. The optical circuit 100 has the connection substrate 50 illustrated in detail in FIG. 3, and has a form of a subassembly that can be mounted, for example, on a substrate such as an Ethernet transceiver. The light-modulating light source chip 40 is an electro-absorption modulator integrated with DFB laser in which optical semiconductor modulators including an optical waveguide structure are integrated, and the electrode length of the electro-absorption modulator (EA modulator) was set to 75 μm. The light-modulating light source chip 40 uses an InP substrate. The material of the connection substrate was aluminum nitride, the width of the transmission line 31 of the connection substrate 30 was set to 0.08 mm, and the distance d from the center line along the length direction of the transmission line 31 to the ground electrode 35 was set to 0.08 mm. The thickness T of the connection substrate 30 was set to 0.15 mm or more so as not to affect the characteristic impedance when the characteristic impedance of the transmission line 31 is 50Ω.

The capacitance of the mounted capacitor 57 was set to 100 nF. In order to compare modulation characteristics, an optical circuit according to the configuration of the related art illustrated in FIG. 1 was also produced. The bias current of the laser section of the light-modulating light source chip 40 was set to 80 mA, and the bias voltage of the EA modulator was set to −1.4 V. In all the produced optical circuits, the gold bumps 32a, 32b, and 33 used for connection between the connection substrate 50 and the wiring board 20 and the light-modulating light source chip 40 had a diameter of 60 μm and a height of 30 μm.

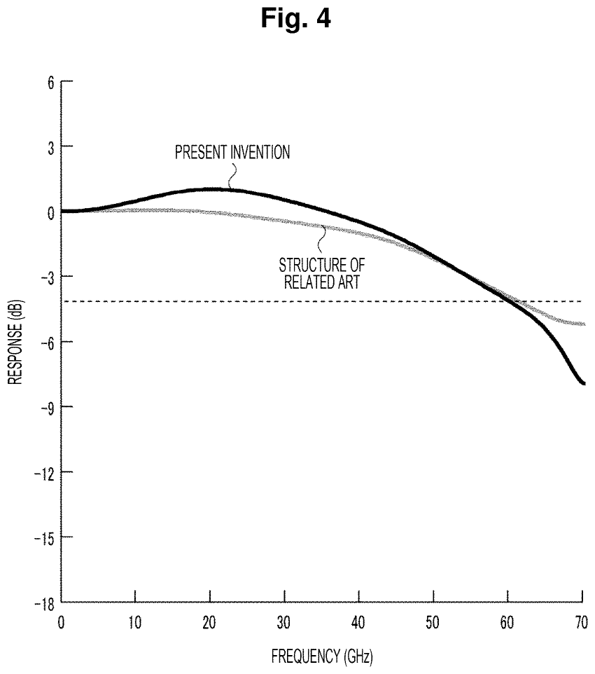

FIG. 4 is a diagram illustrating comparison of modulation frequency characteristics between the optical circuits having the respective configurations of Example 1 and the related art. The horizontal axis indicates the modulation frequency (GHz), and the vertical axis indicates the frequency response of the modulation output characteristics normalized at a level near the direct current in dB. While a 3 dB band was 54 GHz in optical circuit having the configuration of the related art, an equivalent 3 dB band of 54 GHz was obtained also in the optical circuit having the configuration of Example 1. In addition, in the modulation frequency characteristics having the configuration of Example 1, the peaking level is higher by 1 dB at maximum than in the case of the configuration of the related art. In the optical circuit of the related art, the current value of the EA bias was −39 mA and the total power consumption was 0.0546 W, whereas in the optical circuit of Example 1, the EA bias current was −11 mA and the total power consumption was 0.0154 W. The power consumption can be reduced to ⅓ or less as compared with the case where the capacitor of the related art is not provided.

From the modulation frequency characteristics of FIG. 4, it has been confirmed that the optical circuit having the configuration of Example 1 can obtain a bandwidth almost the same as that of the configuration of the related art and a larger peaking, and is effective for broadening the bandwidth of the light-modulating light source. In addition, since the capacitor is not mounted on the subcarrier, it matches the tendency of miniaturization of the optical circuit, and is also useful for suppressing power consumption. In the following Example 2, another configuration example in which a capacitor is mounted on a connection substrate for an optical circuit including another light source chip including a Mach-Zehnder interferometric modulator (MZ modulator) instead of the EA modulator will be described.

### Example 2

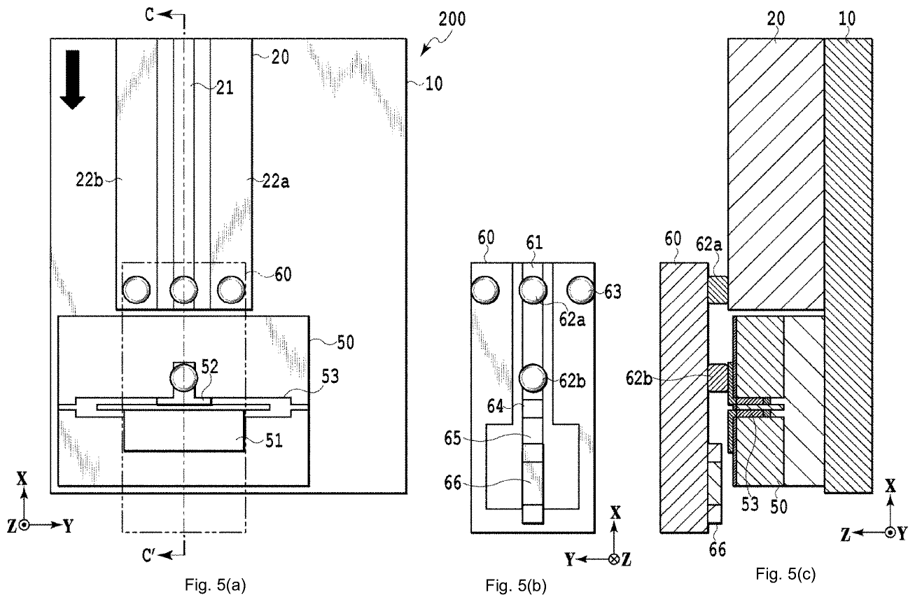

FIG. 5 is a diagram illustrating a configuration of Example 2 of the optical circuit of the present disclosure including the light-modulating light source chip. The optical circuit of Example 2 has a form of a subassembly 200 that can be mounted, for example, in an Ethernet transceiver or on a package such as an optical transmission device. In FIG. 5, (a) illustrates a top view (x-y plane) of the entire optical circuit 200, (c) illustrates a cross-sectional view (x-z plane) of the optical circuit 200 taken along line C-C′, and (b) illustrates a back surface (x-y plane) of a connection substrate 60 on which the capacitor mounted on the optical circuit 200 is mounted. The optical circuit 200 of Example 2 has an optical modulator chip (light source chip) 50 including only a Mach-Zehnder interferometric modulator (MZ modulator) 53 without including a light source, instead of the light-modulating light source chip 40 of Example 1.

As can be seen from the cross-sectional view of (c) of FIG. 5, the MZ modulator 53 configured in the optical modulator chip 50 has two arm waveguide structures. A modulation input electrode 52 (P-side electrode) as an input terminal of a high-frequency electrical signal is formed on one arm waveguide, and a P-side electrode 51 for phase adjustment is formed on the other arm waveguide.

The wiring board 20 mounted on the subcarrier 10 and the optical modulator chip 50 are connected by the connection substrate 60, and the high-frequency electrical signal is input to a modulation input electrode 52 from the outside of the optical circuit 200. A transmission line (signal line) leading to the optical modulator chip 50 via the wiring board 20 and the connection substrate 60, and a connection form on the ground substrate and chip are the same as those in Example 1.

As illustrated in FIG. 3, in the connection substrate 50 of Example 1, the capacitor 57 was mounted on the second surface opposite to the first surface (connection surface) on which the transmission line is formed. In Example 2, unlike Example 1, a capacitor 66 of the connection substrate 60 is mounted on the first surface (connection surface) connected to the wiring board 20 and the optical modulator chip 50 by gold bumps 62a, 62b, and 63.

In the connection substrate 60, a termination resistor 64, a high impedance line 65, and the capacitor 66 are connected in series, and as an electric circuit, this series circuit is inserted between the modulation input terminal and the ground. With such a configuration, when a bias voltage is applied to the optical modulator chip 50, the bias current can be blocked by the capacitor 66 in series with the termination resistor 64.

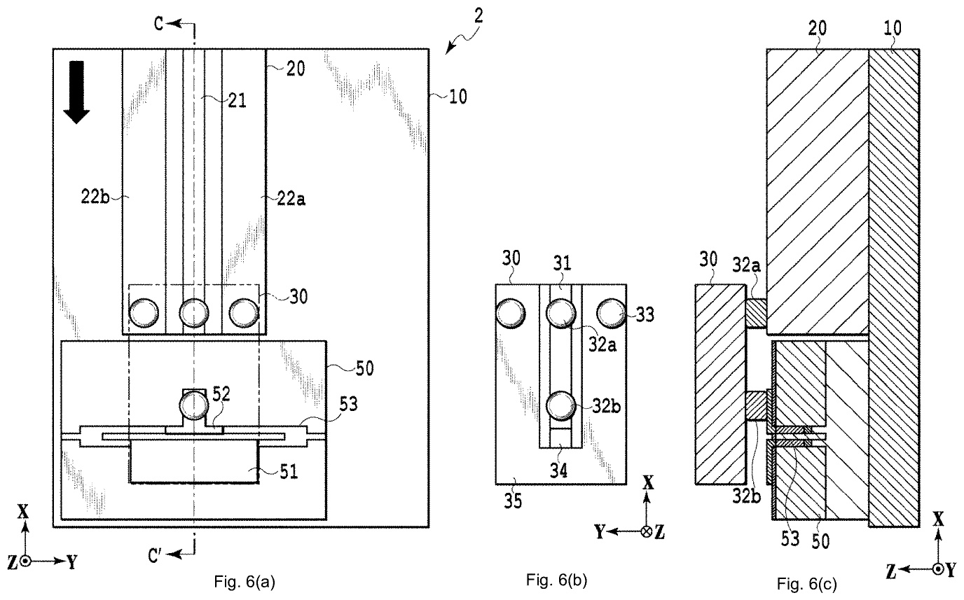

In order to compare the modulation frequency characteristics of the optical circuit of Example 2 with the configuration of the related art, an optical circuit using an optical modulator chip of the configuration of the related art in which a capacitor is not provided as illustrated in FIG. 1 was produced. FIG. 6 is a diagram illustrating a configuration of an optical circuit having a configuration of the related art using an MZ modulator. In FIG. 6, (a) illustrates a top view (x-y plane) of the entire optical circuit 2, (c) illustrates a cross-sectional view (x-z plane) of the optical circuit taken along line C-C′, and (b) illustrates a back surface (x-y plane) of the connection substrate 30 mounted on the optical circuit. As compared with the configuration of Example 2 in FIG. 5, in the connection substrate 30, the termination resistor 34 is directly connected to the ground 35, and the current constantly flows through the termination resistor 34 by the bias voltage applied to the modulation input electrode 52.

The optical modulator chip 50 in FIGS. 5 and 6 is a Mach-Zehnder modulator (MZ modulator), and the electrode length of the MZ modulator was set to 100 μm. The optical modulator chip 50 uses an InP substrate. The capacitance of the capacitor 66 mounted in the optical circuit of Example 2 in FIG. 5 was set to 10 nF. The input optical power to the optical modulator chip 50 of FIGS. 5 and 6 was set to +8 dBm, and the bias voltage of the MZ modulator was set to −1.5 V.

The material of the connection substrate 60 was aluminum nitride, the width of a transmission line 61 of the connection substrate 60 was set to 0.08 mm, and the distance d from the center line along the length direction of the transmission line 61 to the ground electrode 35 was set to 0.08 mm. The thickness T of the connection substrate 60 was set to 0.15 mm or more so as not to affect the characteristic impedance when the characteristic impedance of the transmission line 61 is 50Ω.

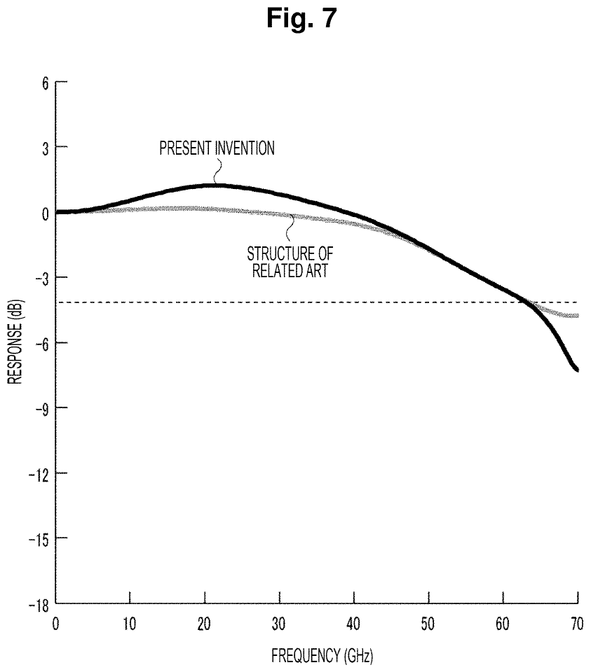

FIG. 7 is a diagram illustrating comparison of modulation frequency characteristics between the optical circuits having the respective configurations of Example 2 and the related art. The horizontal axis indicates the modulation frequency (GHz), and the vertical axis indicates the frequency response of the modulation output characteristics normalized at a level near the direct current in dB. While a 3 dB band was 57 GHz in the optical circuit 2 having the configuration of the related art illustrated in FIG. 6, an equivalent 3 dB band of 57 GHz was obtained also in the optical circuit 200 having the configuration of Example 2 illustrated in FIG. 5. In addition, in the modulation frequency characteristics of the optical circuit 200 having the configuration of Example 2, the peaking level is 1 dB or more higher than in the case of the configuration of the related art.

In the optical circuit 2 having the configuration of the related art, the bias current value of the MZ modulator was −35 mA and the total power consumption was 0.0525 W, whereas in the optical circuit 200 of Example 2, the bias current of the MZ modulator was −5 mA and the total power consumption was 0.0075 W. The power consumption due to the bias current can be reduced to 1/7 as compared with the case of the optical circuit having the configuration in which the capacitor of the related art is not provided.

From the modulation frequency characteristics of FIG. 7, it has been confirmed that even the optical circuit having the configuration of Example 2 can obtain a bandwidth almost the same as that of the configuration of the related art and a larger peaking, and is effective for broadening the bandwidth of the light-modulating light source. In addition, since the capacitor is not mounted on the subcarrier, it matches the tendency of miniaturization of the optical circuit, and power consumption can be suppressed.

As described above, the optical circuit of the present disclosure achieves an optical circuit including an optical modulator that is suitable for high-speed operation, miniaturized, and highly reliable.

### INDUSTRIAL APPLICABILITY

The present invention can be used for a network device for optical communication.

1. An optical circuit comprising:
a wiring board that receives a high-frequency electrical signal from the outside;
a light source chip including an optical modulator;
a subcarrier on which the wiring board and the light source chip are mounted;
a connection substrate having, on a first surface, a transmission line connecting between a signal line of the wiring board and a modulation input terminal of the light source chip, and having a termination resistor at one end of the transmission line on a modulation input side; and
a capacitor connected to the ground in series with the termination resistor on the connection substrate.

2. The optical circuit according to claim 1, wherein the capacitor is mounted on the same first surface as the termination resistor via a high impedance line.

3. The optical circuit according to claim 1, wherein the capacitor is connected via a high impedance line extending from the termination resistor to a second surface opposite to the first surface via a side surface of the connection substrate, and is mounted on the second surface.

4. The optical circuit according to claim 1, wherein
the light source chip uses an InP substrate, and
the connection substrate is made of aluminum nitride and has a thickness of 0.15 mm or more.

5. The optical circuit according to claim 1, wherein the light source chip is an electro-absorption modulator or a Mach-Zehnder interferometric modulator.

6. The optical circuit according to claim 1, wherein bumps connect between the signal line and the transmission line and between the transmission line and the modulation input terminal, respectively.

7. The optical circuit according to claim 2, wherein
the light source chip uses an InP substrate, and
the connection substrate is made of aluminum nitride and has a thickness of 0.15 mm or more.

8. The optical circuit according to claim 3, wherein
the light source chip uses an InP substrate, and
the connection substrate is made of aluminum nitride and has a thickness of 0.15 mm or more.

9. The optical circuit according to claim 2, wherein the light source chip is an electro-absorption modulator or a Mach-Zehnder interferometric modulator.

10. The optical circuit according to claim 3, wherein the light source chip is an electro-absorption modulator or a Mach-Zehnder interferometric modulator.

11. The optical circuit according to claim 4, wherein the light source chip is an electro-absorption modulator or a Mach-Zehnder interferometric modulator.

12. The optical circuit according to claim 2, wherein bumps connect between the signal line and the transmission line and between the transmission line and the modulation input terminal, respectively.

13. The optical circuit according to claim 3, wherein bumps connect between the signal line and the transmission line and between the transmission line and the modulation input terminal, respectively.

14. The optical circuit according to claim 4, wherein bumps connect between the signal line and the transmission line and between the transmission line and the modulation input terminal, respectively.

15. The optical circuit according to claim 5, wherein bumps connect between the signal line and the transmission line and between the transmission line and the modulation input terminal, respectively.
